(19) United States
(12) Patent Application Publication
(10) Pub. No.: US 2022/0352088 A1
(43) Pub. Date: Nov. 3, 2022

(54) MODULE

(71) Applicant: Murata Manufacturing Co., Ltd., Kyoto-fu (JP)

(72) Inventors: Tadashi NOMURA, Nagaokakyo-shi (JP); Yukiya YAMAGUCHI, Nagaokakyo-shi (JP); Hiroshi NISHIKAWA, Nagaokakyo-shi (JP); Toru KOMATSU, Nagaokakyo-shi (JP)

(21) Appl. No.: 17/811,113

(22) Filed: Jul. 7, 2022

Related U.S. Application Data
(63) Continuation of application No. PCT/JP2020/046747, filed on Dec. 15, 2020.

(30) Foreign Application Priority Data
Jan. 10, 2020 (JP) 2020-002858

(51) Int. Cl. H01L 23/552; H01L 25/16

(52) U.S. Cl. CPC H01L 23/552; H01L 25/165; H01L 23/66

(57) ABSTRACT

A module includes a substrate including a first surface, at least one first component mounted on the first surface, a shield member mounted on the first surface to cover the first component, and a first sealing resin arranged at least between the shield member and the first surface. The shield member includes a top surface portion in a form of a plate and a plurality of leg portions that extend from the top surface portion toward the first surface.

### CROSS REFERENCE TO RELATED APPLICATION

This is a continuation of International Application No. PCT/JP2020/046747 filed on Dec. 15, 2020 which claims priority from Japanese Patent Application No. 2020-002858 filed on Jan. 10, 2020. The contents of these applications are incorporated herein by reference in their entireties.

### BACKGROUND OF THE DISCLOSURE

### Field of the Disclosure

The present disclosure relates to a module.

### Description of the Related Art

Japanese Patent Laid-Open No. 2011-171390 (PTL 1) describes a shield structure including a shield case that covers a component mounted on a substrate. This shield structure is a sheet-metal shield formed of a sheet metal.

PTL 1: Japanese Patent Laid-Open No. 2011-171390

### BRIEF SUMMARY OF THE DISCLOSURE

In a module with the shield structure as described in PTL 1, resin sealing may be provided to ensure mechanical strength. In a construction described in PTL 1, however, the mounted component is covered with the shield case. Therefore, the mounted component cannot be sealed with a resin and strength may be insufficient.

An object of the present disclosure is to provide a module that can be made in a simplified process and achieves sufficient shielding performance and mechanical strength.

In order to achieve the object, a module based on the present disclosure includes a substrate including a first surface, at least one first component mounted on the first surface, a shield member mounted on the first surface to cover the first component, and a first sealing resin arranged at least between the shield member and the first surface. The shield member includes a top surface portion in a form of a plate and a plurality of leg portions that extend from the top surface portion toward the first surface.

According to the present disclosure, a conductive shield member is constructed to include the top surface portion in the form of the plate and the plurality of leg portions that extend from the top surface portion toward the first surface. Therefore, the first component can sufficiently be shielded. Furthermore, the sealing resin can permeate into the shield member. A module with sufficient shielding performance and mechanical strength can thus be realized.

### BRIEF DESCRIPTION OF THE SEVERAL VIEWS OF THE DRAWINGS

FIG. 1 is a perspective view of a module in a first embodiment based on the present disclosure.

FIG. 2 is a plan view of the module in the first embodiment based on the present disclosure.

FIG. 3 is a plan view with a first sealing resin having been removed from a construction shown in FIG. 2.

FIG. 4 is a plan view with a shield member having been removed from the construction shown in FIG. 3.

FIG. 5 is a cross-sectional view along the line V-V in FIG. 2.

FIG. 6 is a cross-sectional view along the line VI-VI in FIG. 2.

FIG. 7 is a perspective view of the shield member included in the module when viewed in a first direction in the first embodiment based on the present disclosure.

FIG. 8 is a perspective view of the shield member included in the module when viewed in a second direction based on the first embodiment of the present disclosure.

FIG. 9 is a cross-sectional view of a module in a second embodiment based on the present disclosure.

FIG. 10 is a cross-sectional view of a modification of the module in the second embodiment based on the present disclosure.

FIG. 11 is a cross-sectional view of a module in a third embodiment based on the present disclosure.

FIG. 12 is a cross-sectional view of a module in a fourth embodiment based on the present disclosure.

FIG. 13 is a cross-sectional view of a module in a fifth embodiment based on the present disclosure.

FIG. 14 is a cross-sectional view of a modification of the module in the fifth embodiment based on the present disclosure.

FIG. 15 is a cross-sectional view of a module in a sixth embodiment based on the present disclosure.

FIG. 16 is a cross-sectional view of a modification of the module in the sixth embodiment based on the present disclosure.

FIG. 17 is a cross-sectional view of a module in a seventh embodiment based on the present disclosure.

FIG. 18 is a cross-sectional view of a modification of the module in the seventh embodiment based on the present disclosure.

FIG. 19 is a plan view of a module in an eighth embodiment based on the present disclosure.

FIG. 20 is a plan view with the first sealing resin having been removed from a construction shown in FIG. 19.

FIG. 21 is a cross-sectional view along the line XXI-XXI in FIG. 19.

FIG. 22 is a partial plan view with the first sealing resin having been removed, of a first modification of the module in the eighth embodiment based on the present disclosure.

FIG. 23 is a partial plan view with the first sealing resin having been removed, of a second modification of the module in the eighth embodiment based on the present disclosure.

FIG. 24 is a cross-sectional view of a module in a ninth embodiment based on the present disclosure.

### DETAILED DESCRIPTION OF THE DISCLOSURE

A dimensional ratio shown in the drawings does not necessarily faithfully represent an actual dimensional ratio and a dimensional ratio may be exaggerated for the sake of convenience of description. A concept up or upper or down or lower mentioned in the description below does not mean absolute up or upper or down or lower but may mean relative up or upper or down or lower in terms of a shown position.

### First Embodiment

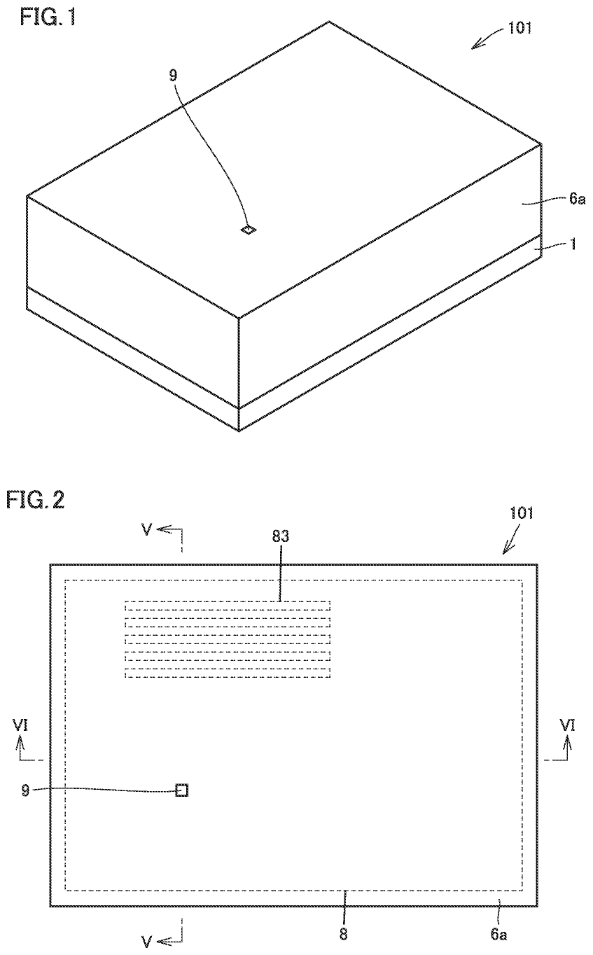

A module in a first embodiment based on the present disclosure will be described with reference to FIGS. 1 to 8. FIG. 1 shows a perspective view of a module 101 in the present embodiment. A substrate 1 is arranged in a lower portion of module 101, and a first sealing resin 6a is arranged in an upper portion thereof. An upper surface and a side surface of first sealing resin 6a are exposed. A marking portion 9 is formed in the upper surface of first sealing resin 6a. Though marking portion 9 like a dot is shown, this is merely by way of example and marking portion 9 may be in another shape.

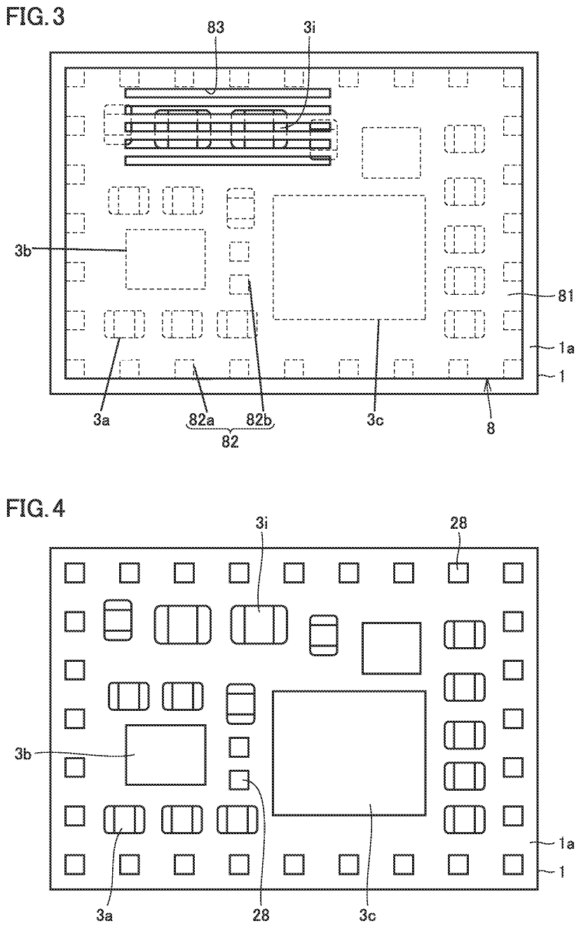

FIG. 2 shows a plan view of module 101. A shield member 8 is arranged in the back of first sealing resin 6a. Since shield member 8 is covered with first sealing resin 6a, it is shown with a dashed line. FIG. 3 shows a state with first sealing resin 6a having been removed from the construction shown in FIG. 2. A surface of substrate 1 on a front side is defined as a first surface 1a. Shield member 8 is mounted on first surface 1a. A slit 83 is provided in shield member 8. A part of an inductor 3i is seen through slit 83.

FIG. 4 shows a state with shield member 8 having been removed from the construction shown in FIG. 3. Components 3a, 3b, and 3c and inductor 3i are mounted on first surface 1a of substrate 1. In an example shown here, though two inductors 3i are mounted on first surface 1a, this is merely by way of example and the number of inductors 3i is not limited to two.

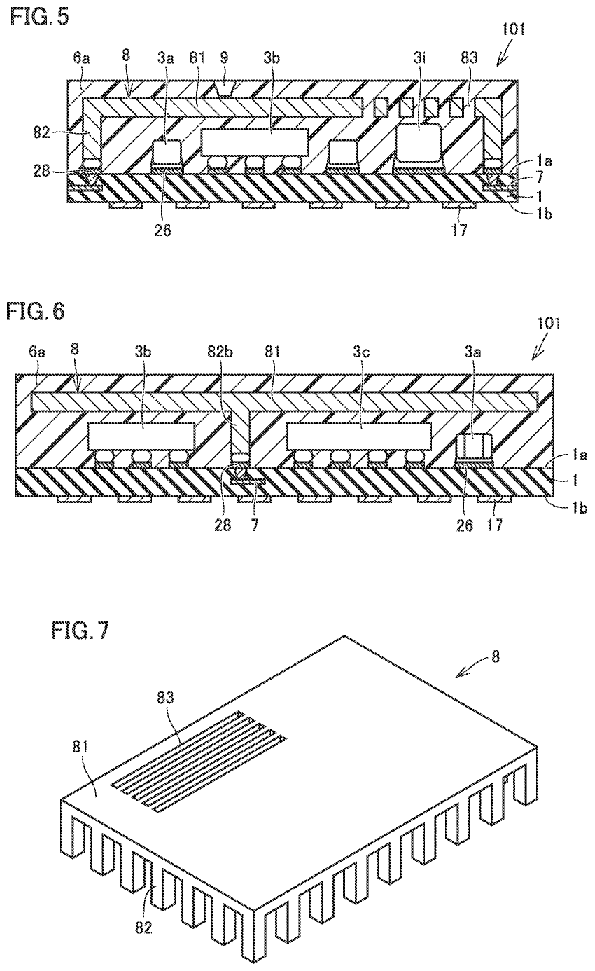

FIG. 5 shows a cross-sectional view along the line V-V in FIG. 2. Substrate 1 includes a second surface 1b on a side opposite to first surface 1a. An external terminal 17 is arranged on second surface 1b. A ground electrode 7 is arranged in the inside of substrate 1. Ground electrode 7 is arranged as being exposed at a side surface of substrate 1. A part of first sealing resin 6a covers an upper surface of a top surface portion 81 of shield member 8. Marking portion 9 is formed in a portion of first sealing resin 6a that extends on an upper side of top surface portion 81 of shield member 8. Marking portion 9 is provided as a recess. When viewed in a direction perpendicular to first surface 1a, as shown in FIG. 2, first sealing resin 6a extends to an outer side of shield member 8. In FIG. 5, first sealing resin 6a is formed as extending off shield member 8 and spreading laterally. FIG. 6 shows a cross-sectional view along the line VI-VI in FIG. 2.

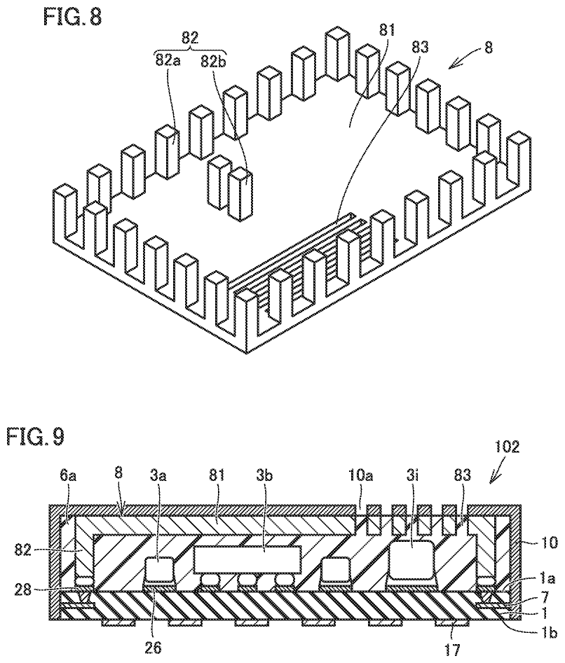

FIG. 7 shows independently extracted shield member 8. FIG. 8 shows shield member 8 when viewed from the back. Shield member 8 is integrally formed of a metal. Shield member 8 is made, for example, of copper. Shield member 8 can be formed, for example, by press-working a metal plate. Shield member 8 is made as an independent metal component in advance and mounted on first surface 1a. As shown in FIGS. 7 and 8, shield member 8 includes top surface portion 81 and a plurality of leg portions 82. A plurality of slits 83 are provided in top surface portion 81. As shown in FIG. 8, the plurality of leg portions 82 include a first leg portion 82a and a second leg portion 82b. Though twenty-eight first leg portions 82a and two second leg portions 82b are disposed in the example shown in FIG. 8, this is merely by way of example. The number of first leg portions 82a and the number of second leg portions 82b are not limited to the numbers as shown. Though the plurality of leg portions 82 each have a square cross-sectional shape in the example here, this is merely by way of example. Each of the plurality of leg portions 82 may have a cross-sectional shape other than the square. As shown in FIG. 6, second leg portion 82b is located between components 3b and 3c. Second leg portion 82b brings the shield effect of preventing electromagnetic interference between components 3b and 3c.

The construction of module 101 can be summarized as below. Module 101 in the present embodiment includes substrate 1 including first surface 1a, at least one first component mounted on first surface 1a, shield member 8 mounted on first surface la to cover the first component, and first sealing resin 6a arranged at least between shield member 8 and first surface 1a. First sealing resin 6a is arranged to fill a space at least between shield member 8 and first surface 1a.

Substrate 1 is a wiring board. Substrate 1 is made by layering a plurality of insulated layers. Substrate 1 may be a ceramic multilayer substrate or a resin multilayer substrate such as a printed circuit board. In the present embodiment, components 3a, 3b, and 3c and inductor 3i mounted on first surface 1a of substrate 1 correspond to the “at least one first component.” In the present embodiment, first sealing resin 6a not only fills the space between top surface portion 81 of shield member 8 and first surface 1a but also covers a surface of top surface portion 81 on a side far from first surface 1a.

Shield member 8 is conductive. Shield member 8 includes top surface portion 81 in a form of a plate and a plurality of leg portions 82 that extend from top surface portion 81 toward first surface 1a. Each of the plurality of leg portions 82 has a tip end electrically connected to first surface 1a. Specifically, each of the plurality of leg portions 82 has the tip end soldered to a ground electrode 28 arranged on first surface 1a. In forming first sealing resin 6a, a fluid material for first sealing resin 6a passes through between the plurality of leg portions 82 to enter the space between top surface portion 81 of shield member 8 and first surface 1a. Therefore, an interval between leg portions 82 is preferably larger than a maximum diameter of a filler contained in first sealing resin 6a.

In the present embodiment, since conductive shield member 8 is mounted on first surface 1a to cover the first component, the first component can sufficiently be shielded. Therefore, a module that can be made in a simplified process and achieves sufficient shielding performance can be realized.

As shown in the present embodiment, the plurality of leg portions 82 preferably include first leg portion 82a that extends from the outer peripheral portion of top surface portion 81 toward first surface 1a and second leg portion 82b that extends from the middle portion of top surface portion 81 toward first surface 1a. By adopting this construction, electrical connection to first surface 1a can be made through a short path not only in the vicinity of the outer peripheral portion of top surface portion 81 of shield member 8 but also from the middle portion thereof. Therefore, connection to the ground electrode of substrate 1 can be made with a resistance being suppressed. The “middle portion” herein means a portion other than the outer peripheral portion. A region on an inner side surrounded by the outer peripheral portion fully falls under the middle portion.

As shown in the present embodiment, preferably, the at least one first component includes inductor 3i, and when viewed in the direction perpendicular to first surface 1a, top surface portion 81 includes a plurality of slits 83 in the region superimposed on inductor 3i. By adopting this construction, generation of an eddy current in top surface portion 81 due to magnetic field created by inductor 3i can be suppressed. Consequently, degradation of a quality factor of inductor 3i due to influence by the eddy current can be lessened. In forming first sealing resin 6a, a fluid material for first sealing resin 6a preferably freely passes through slits 83. Therefore, slit 83 preferably has a width slightly larger than the maximum diameter of the filler contained in first sealing resin 6a.

As shown in the present embodiment, preferably, first sealing resin 6a covers the surface of top surface portion 81 on the side far from first surface 1a. By adopting this construction, shield member 8 can be protected by first sealing resin 6a. In particular, in an example where shield member 8 is made of a material prone to be oxidized by contact with air, oxidation of shield member 8 can be prevented by covering shield member 8 with first sealing resin 6a so as not to be exposed.

As shown in the present embodiment, preferably, marking portion 9 is formed in a portion of first sealing resin 6a that covers top surface portion 81. By adopting this construction, marking portion 9 can serve as a mark for identification. Alternatively, information on the module can also be shown by forming marking portion 9 as a character, a sign, or a figure. Laser processing may be used for forming marking portion 9. In connection with irradiation of the surface of first sealing resin 6a with laser beams, such a phenomenon as undesirable entry of laser beams deep in the back of first sealing resin 6a through the filler contained in first sealing resin 6a has been known. Break of a component by entry of such laser beams is a concern. As shown in the present embodiment, however, with the construction in which top surface portion 81 of shield member 8 is located on the inner side of first sealing resin 6a, laser beams that enter the inside of first sealing resin 6a are cut off by top surface portion 81. Therefore, such a situation as break of the first component by undesirably entering laser beams can be prevented.

### Second Embodiment

A module in a second embodiment based on the present disclosure will be described with reference to FIG. 9. FIG. 9 shows a cross-sectional view of a module 102 in the present embodiment. Module 102 is common in basic construction to module 101 shown in the first embodiment.

In module 102 in the present embodiment, first sealing resin 6a does not cover an upper side of top surface portion 81. The upper surface of first sealing resin 6a and an upper surface of shield member 8 are flush with each other. An outer shield film 10 is formed to cover the side surface and the upper surface of first sealing resin 6a. Outer shield film 10 covers also the side surface of substrate 1. Outer shield film 10 is conductive. Outer shield film 10 is composed, for example, of stainless steel. Outer shield film 10 can be formed, for example, by sputtering. Outer shield film 10 may be made by layering a plurality of types of films. In this case, at least any one of the films included in outer shield film 10 is conductive. Though the upper surface of shield member 8 is not covered with first sealing resin 6a but is exposed, the upper surface of shield member 8 is also covered with outer shield film 10. As shown in FIG. 9, a slit 10a is provided in an upper surface of outer shield film 10 in correspondence with slit 83 provided in shield member 8. First sealing resin 6a is slightly seen through slit 10a. Marking portion 9 may be formed in the upper surface of shield member 8 and may be covered with outer shield film 10.

As shown in FIG. 9, ground electrode 7 arranged in the inside of substrate 1 is exposed at the side surface of substrate 1. In the side surface of substrate 1, an end surface of ground electrode 7 and outer shield film 10 are electrically connected to each other.

The construction of module 102 in the present embodiment can be expressed as below. When viewed in the direction perpendicular to first surface 1a, first sealing resin 6a extends to the outer side of shield member 8. Module 102 includes outer shield film 10 that covers the side surface of first sealing resin 6a and the upper surface of first sealing resin 6a or the upper surface of shield member 8.

An effect similar to the effect described in the first embodiment can be obtained also in the present embodiment. Since module 102 in the present embodiment includes outer shield film 10, outer shield film 10 protects first sealing resin 6a and shield member 8. In the present embodiment, though main shielding performance is secured by shield member 8 arranged to cover the first component, outer shield film 10 further surrounds the outer side thereof. Therefore, more reliable shielding performance can be achieved.

In the example shown here, the upper surface of shield member 8 is not covered with first sealing resin 6a but is exposed, and the upper surface of shield member 8 is in contact with outer shield film 10. The upper surface of shield member 8, however, may be covered with first sealing resin 6a and the upper surface of first sealing resin 6a may be covered with outer shield film 10. In other words, a part of first sealing resin 6a may be arranged between the upper surface of shield member 8 and outer shield film 10.

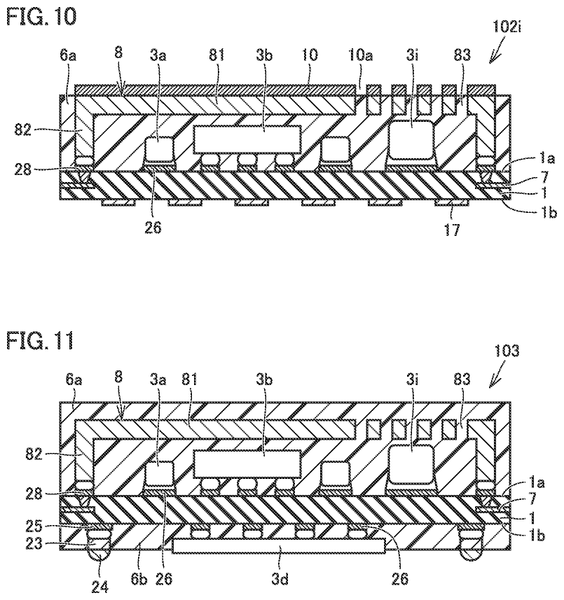

A construction like a module 102i shown in FIG. 10 may further be applicable. In module 102i, outer shield film 10 is formed to cover only the upper surface of shield member 8 exposed through first sealing resin 6a. This construction can be made by forming outer shield film 10, for example, by electroplating.

### Third Embodiment

A module in a third embodiment based on the present disclosure will be described with reference to FIG. 11. FIG. 11 shows a cross-sectional view of a module 103 in the present embodiment. Module 103 is common in basic construction to module 101 shown in the first embodiment.

Unlike module 101 shown in the first embodiment, module 103 in the present embodiment has a double-sided mount structure. Specifically, the construction is as below. Substrate 1 includes a second surface 1b as a surface opposite to first surface 1a. At least one second component is mounted on second surface 1b. A second sealing resin 6b is arranged to cover the second component and second surface 1b. In the example shown here, a component 3d is mounted on second surface 1b. Component 3d corresponds to the “at least one second component.”

A surface of component 3d on a side far from second surface 1b is exposed through second sealing resin 6b. The surface of component 3d on the side far from second surface 1b may be flush with a surface of second sealing resin 6b on the side far from second surface 1b. As shown in FIG. 11, component 3d may protrude from second sealing resin 6b. Alternatively, component 3d may be covered with second sealing resin 6b.

An electrode 25 is arranged on the second surface of substrate 1. A columnar conductor 23 is soldered to electrode 25. Columnar conductor 23 passes through second sealing resin 6b. Columnar conductor 23 has a lower end exposed through second sealing resin 6b and a solder bump 24 is connected to the lower end of columnar conductor 23. Solder bump 24 does not have to be provided. Columnar conductor 23 may be formed from any one of a protruding electrode, a metal pin, and a metal block. Columnar conductor 23 may be formed by plating. Instead of columnar conductor 23, a solder bump may be employed.

An effect similar to the effect described in the first embodiment can be obtained also in the present embodiment. Since the double-sided mount structure is adopted in the present embodiment, a larger number of components can be mounted on substrate 1.

### Fourth Embodiment

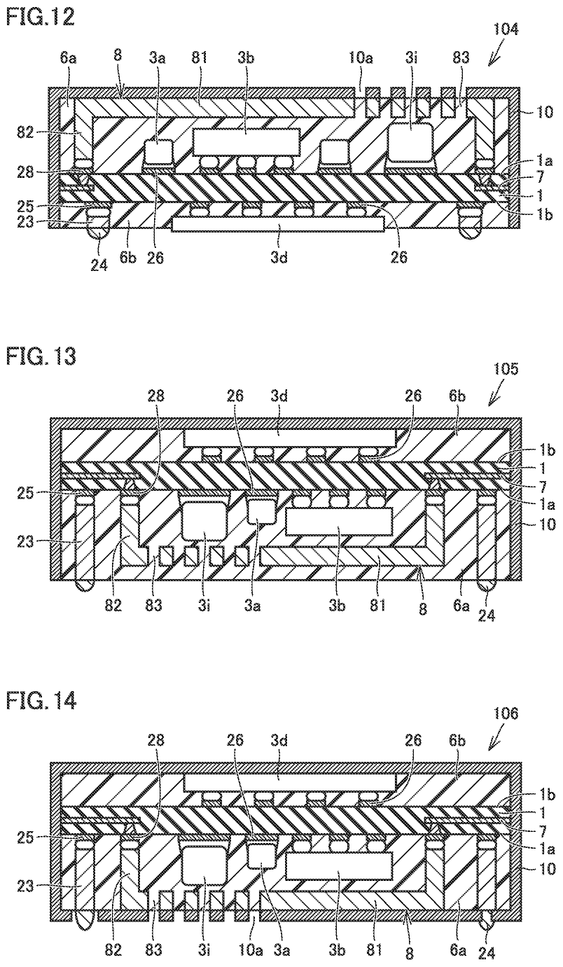

A module in a fourth embodiment based on the present disclosure will be described with reference to FIG. 12. FIG. 12 shows a cross-sectional view of a module 104 in the present embodiment. Module 104 is common in basic construction to module 103 shown in the third embodiment.

Module 104 in the present embodiment includes outer shield film 10. Outer shield film 10 collectively covers the side surface of first sealing resin 6a, the side surface of substrate 1, and a side surface of second sealing resin 6b. Outer shield film 10 further collectively covers the upper surface of shield member 8 and the upper surface of first sealing resin 6a. A lower surface of second sealing resin 6b is exposed.

An effect similar to the effect described in the third embodiment can be obtained also in the present embodiment. Since outer shield film 10 is provided in the present embodiment, the effect described in the second embodiment can also be obtained.

### Fifth Embodiment

A module in a fifth embodiment based on the present disclosure will be described with reference to FIG. 13. FIG. 13 shows a cross-sectional view of a module 105 in the present embodiment. Module 105 has a double-sided mount structure. In module 105, first surface 1a of substrate 1 faces down and second surface 1b faces up. Since shield member 8 is mounted on first surface 1a, shield member 8 is arranged below substrate 1. Columnar conductor 23 is arranged on first surface 1a. Columnar conductor 23 is arranged to pass through first sealing resin 6a. A lower surface of first sealing resin 6a is not covered with outer shield film 10 but is exposed. In the present embodiment, columnar conductor 23 and shield member 8 are arranged on the same surface of substrate 1.

An effect as described in the fourth embodiment can be obtained also in the present embodiment.

(Modification)

A module 106 shown in FIG. 14 corresponds to a modification of module 105. As in module 106, outer shield film 10 may cover the lower surface of first sealing resin 6a. Outer shield film 10 includes an opening. Solder bump 24 connected to the lower end of columnar conductor 23 protrudes through the opening in outer shield film 10. In a case of grounded columnar conductor 23, solder bump 24 connected to the lower end thereof may electrically be connected to outer shield film 10.

### Sixth Embodiment

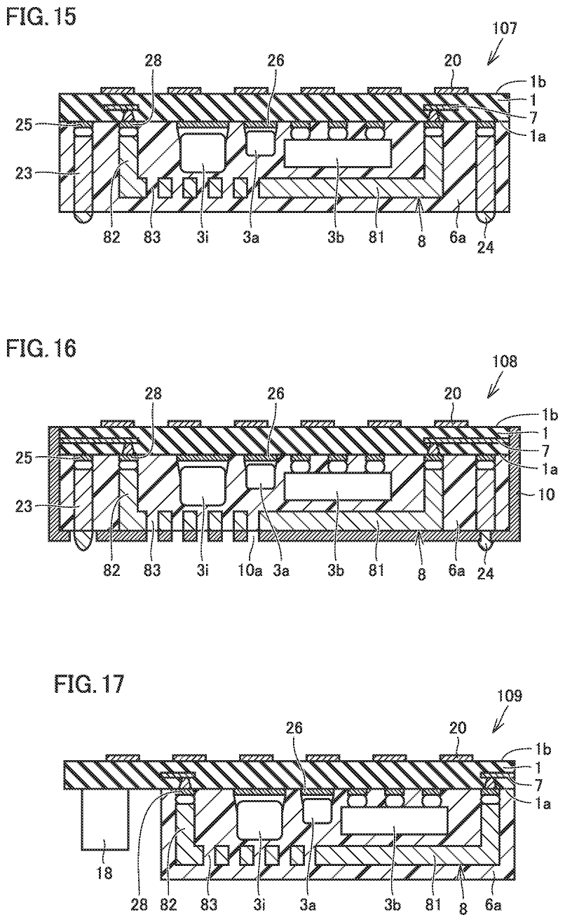

A module in a sixth embodiment based on the present disclosure will be described with reference to FIG. 15. FIG. 15 shows a cross-sectional view of a module 107 in the present embodiment.

In module 107, substrate 1 includes second surface 1b as the surface opposite to first surface 1a. An antenna electrode 20 is arranged on second surface 1b. In module 107, first surface 1a of substrate 1 faces down and second surface 1b faces up. Components 3a, 3b, and 3i are mounted on first surface 1a. Columnar conductor 23 is soldered to electrode 25 arranged on first surface 1a. Columnar conductor 23 is arranged to pass through first sealing resin 6a.

An effect as described in the first embodiment can be obtained also in the present embodiment.

(Modification)

A module 108 shown in FIG. 16 corresponds to a modification of module 107. As in module 108, outer shield film 10 may cover the side surface and the lower surface of first sealing resin 6a. Outer shield film 10 includes an opening. Solder bump 24 connected to the lower end of columnar conductor 23 protrudes through the opening in outer shield film 10. In module 108, outer shield film 10 covers also the side surface of substrate 1. On the side surface of substrate 1, ground electrode 7 is electrically connected to outer shield film 10.

### Seventh Embodiment

A module in a seventh embodiment based on the present disclosure will be described with reference to FIG. 17. FIG. 17 shows a cross-sectional view of a module 109 in the present embodiment. In module 109, antenna electrode 20 is arranged on second surface 1b of substrate 1. In module 109, a connector 18 is arranged on first surface 1a of substrate 1. Components 3a and 3b and inductor 3i are mounted on first surface 1a of substrate 1. Shield member 8 is arranged to cover components 3a and 3b and inductor 3i. Connector 18 is not covered with shield member 8. First sealing resin 6a is formed to seal shield member 8. First sealing resin 6a is arranged to avoid connector 18. In other words, first sealing resin 6a partially seals first surface 1a.

An effect as described in the sixth embodiment can be obtained also in the present embodiment. Since connector 18 is arranged on first surface 1a of substrate 1 in the present embodiment, connection to the outside can readily be made.

(Modification)

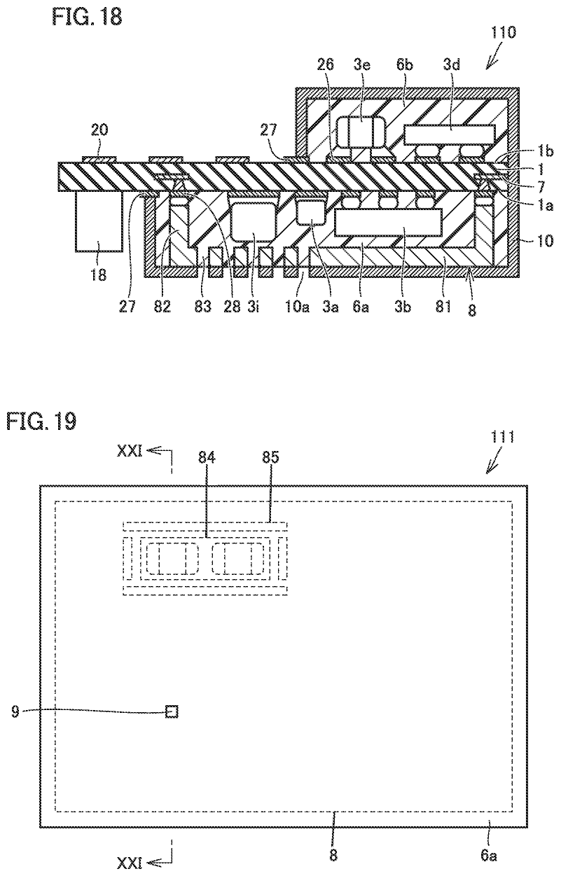

A module 110 shown in FIG. 18 corresponds to a modification of module 109. In module 110, antenna electrode 20 is arranged in a partial region of second surface 1b of substrate 1, and an electrode 26 and a ground electrode 27 are arranged in another partial region. Components 3d and 3e are mounted with electrode 26 being interposed. Second sealing resin 6b is formed to cover components 3d and 3e and a part of second surface 1b. Outer shield film 10 is formed to cover the side surface and the lower surface of first sealing resin 6a, the side surface of substrate 1, and the side surface and an upper surface of second sealing resin 6b. Outer shield film 10 is electrically connected to ground electrode 27 at second surface 1b. Another ground electrode 27 is arranged also on first surface 1a, and outer shield film 10 is electrically connected to ground electrode 27 also at first surface 1a. As shown in module 110, first surface 1a and second surface 1b may be different from each other in region covered with the sealing resin.

### Eighth Embodiment

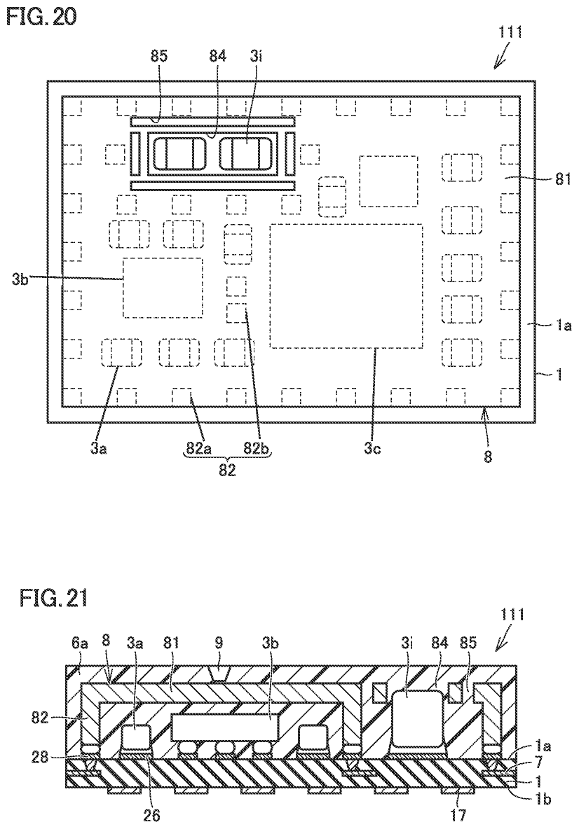

A module in an eighth embodiment based on the present disclosure will be described with reference to FIGS. 19 to 21. FIG. 19 shows a plan view of a module 111 in the present embodiment. Shield member 8 is arranged in the back of first sealing resin 6a. FIG. 20 shows a state with first sealing resin 6a having been removed from the construction shown in FIG. 19. A surface of substrate 1 on a front side is defined as first surface 1a. Shield member 8 is mounted on first surface 1a. An opening 84 and a slit 85 are provided in shield member 8. The entire inductor 3i is seen through opening 84. Four slits 85 are arranged to surround single opening 84. Though two inductors 3i are mounted on first surface 1a in the example shown here, this is merely by way of example, and the number of inductors 3i is not limited to two.

FIG. 21 shows a cross-sectional view along the line XXI-XXI in FIG. 19. Features such as substrate 1 and first sealing resin 6a are similar to those described in the first embodiment.

In the present embodiment, the “at least one first component” includes inductor 3i. Top surface portion 81 includes opening 84 in a first region including a projected area of inductor 3i and includes a plurality of slits 85 in a second region that surrounds the first region. A part of inductor 3i is located in opening 84.

As shown in FIG. 21, an upper surface of inductor 3i is located above a lower surface of top surface portion 81. Though the upper surface of inductor 3i is located below the upper surface of top surface portion 81, they may be flush with each other. The upper surface of inductor 3i may be located above the upper surface of top surface portion 81.

In the present embodiment, top surface portion 81 includes opening 84 and a part of inductor 3i is located in opening 84. Therefore, the entire module 111 can be low in profile. Furthermore, since the plurality of slits 85 are arranged in the second region that surrounds the first region where opening 84 is arranged, generation of the eddy current in top surface portion 81 due to magnetic field created by inductor 3i therearound can be suppressed. Consequently, degradation of the quality factor of inductor 3i due to influence by the eddy current can be lessened.

(First Modification)

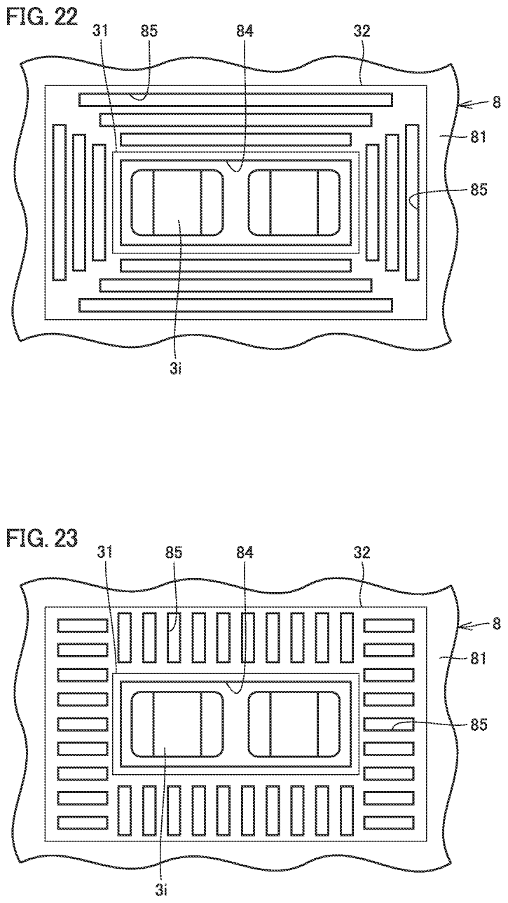

A first modification of the module in the present embodiment will be described. The module in the first modification includes features shown in FIG. 22. FIG. 22 shows as being enlarged, only the vicinity of opening 84 with first sealing resin 6a having been removed from the module. FIG. 22 shows a first region 31 and a second region 32 with a thin solid line.

In the module as the first modification, the “at least one first component” includes inductor 3i. Top surface portion 81 includes opening 84 in first region 31 including the projected area of inductor 3i and includes the plurality of slits 85 in second region 32 that surrounds first region 31. A part of inductor 3i is located in opening 84. A plurality of slits 85 are provided for each side of opening 84. Each slit 85 is provided such that a direction in parallel to the side of opening 84 is defined as a longitudinal direction. With such a construction, slit 85 can be disposed at a position distant to some extent from inductor 3i. Therefore, generation of the eddy current can more reliably be suppressed even at a position distant to some extent from inductor 3i.

(Second Modification)

A second modification of the module in the present embodiment will be described. The module in the second modification includes features shown in FIG. 23. FIG. 23 shows as being enlarged, only the vicinity of opening 84 with first sealing resin 6a having been removed from the module.

In the module as the second modification, the “at least one first component” includes inductor 3i. Top surface portion 81 includes opening 84 in first region 31 including the projected area of inductor 3i and includes the plurality of slits 85 in second region 32 that surrounds first region 31. A part of inductor 3i is located in opening 84. The plurality of slits 85 are disposed to fill second region 32. Many of these slits 85 are provided such that a direction perpendicular to the side of opening 84 is defined as the longitudinal direction. With such a construction, slit 85 can be disposed even at a position distant to some extent from inductor 3i. Therefore, generation of the eddy current can more reliably be suppressed even at a position distant to some extent from inductor 3i. In the second modification as compared with the first modification, a bar-shaped portion made of a conductive material, of top surface portion 81 that lies between slits 85 can be shorter in length, and hence an electrical resistance around opening 84 can be suppressed.

### Ninth Embodiment

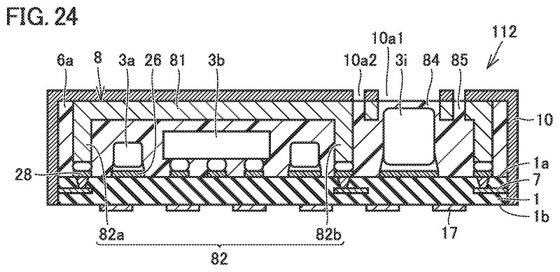

A module in a ninth embodiment based on the present disclosure will be described with reference to FIG. 24. FIG. 24 shows a cross-sectional view of a module 112 in the present embodiment. Module 112 is common in basic construction to module 111 shown in the eighth embodiment.

Module 112 in the present embodiment is similar also to module 102 shown in the second embodiment. In module 112, outer shield film 10 is formed to cover the side surface and the upper surface of first sealing resin 6a. Though the upper surface of shield member 8 is not covered with first sealing resin 6a but is exposed, this upper surface is also covered with outer shield film 10.

Outer shield film 10 includes an opening 10a1 corresponding to opening 84 and a slit 10a2 corresponding to slit 85. The upper surface of inductor 3i is covered with first sealing resin 6a.

An effect similar to the effect described in the eighth embodiment can be obtained also in the present embodiment. In other words, the entire module 112 can be low in profile. Since module 112 in the present embodiment includes outer shield film 10, outer shield film 10 protects first sealing resin 6a and shield member 8. Though main shielding performance is secured by shield member 8 arranged to cover the first component in the present embodiment, outer shield film 10 further surrounds the outer side thereof. Therefore, more reliable shielding performance can be achieved.

Some features in embodiments above may be adopted as being combined as appropriate.

It should be understood that the embodiments disclosed herein are illustrative and non-restrictive in every respect. The scope of the present disclosure is defined by the terms of the claims and is intended to include any modifications within the scope and meaning equivalent to the terms of the claims.

1 substrate; 1a first surface; 1b second surface; 3a, 3b, 3c, 3d, 3e component; 3i inductor; 6a first sealing resin; 6b second sealing resin; 7, 27, 28 ground electrode; 8 first member; 9 marking portion; 10 outer shield film; 10a slit (provided in outer shield film); 17 external terminal; 18 connector; 20 antenna electrode; 23 columnar conductor; 24 solder bump; 25, 26 electrode; 31 first region; 32 second region; 81 top surface portion; 82 leg portion; 82a first leg portion; 82b second leg portion; 83, 85 slit; 84 opening; 101, 102, 102i, 103, 104, 105, 106, 107, 108, 109, 110, 111, 112 module

1. A module comprising:
a substrate including a first surface;
at least one first component mounted on the first surface;
a shield member mounted on the first surface to cover the first component; and
a first sealing resin arranged at least between the shield member and the first surface,
the shield member including a top surface portion in a form of a plate and a plurality of leg portions extending from the top surface portion toward the first surface.

2. The module according to claim 1, wherein
the plurality of leg portions include a first leg portion extending from an outer peripheral portion of the top surface portion toward the first surface and a second leg portion extending from a middle portion of the top surface portion toward the first surface.

3. The module according to claim 1, wherein
the at least one first component includes an inductor, and
when viewed in a direction perpendicular to the first surface, the top surface portion includes a plurality of slits in a region superimposed on the inductor.

4. The module according to claim 1, wherein
the at least one first component includes an inductor, and
the top surface portion includes an opening in a first region including a projected area of the inductor and a plurality of slits in a second region surrounding the first region.

5. The module according to claim 1, wherein
the first sealing resin covers a surface of the top surface portion on a side farther from the first surface.

6. The module according to claim 5, wherein
a portion of the first sealing resin covering the top surface portion includes a marking portion.

7. The module according to claim 1, wherein
when viewed in a direction perpendicular to the first surface, the first sealing resin extends to an outer side of the shield member, and
the module comprises an outer shield film covering a side surface of the first sealing resin and covering an upper surface of the first sealing resin or an upper surface of the shield member.

8. The module according to claim 1, wherein
the substrate includes a second surface as a surface opposite to the first surface,
at least one second component is mounted on the second surface, and
a second sealing resin is arranged to cover the second component and the second surface.

9. The module according to claim 1, wherein
the substrate includes a second surface as a surface opposite to the first surface, and
an antenna electrode is arranged on the second surface.

10. The module according to claim 2, wherein
the at least one first component is at least two first components, and the second leg portion is located between the first components.

11. The module according to claim 2, wherein
the at least one first component includes an inductor, and
when viewed in a direction perpendicular to the first surface, the top surface portion includes a plurality of slits in a region superimposed on the inductor.

12. The module according to claim 2, wherein
the at least one first component includes an inductor, and
the top surface portion includes an opening in a first region including a projected area of the inductor and a plurality of slits in a second region surrounding the first region.

13. The module according to claim 2, wherein
the first sealing resin covers a surface of the top surface portion on a side farther from the first surface.

14. The module according to claim 3, wherein
the first sealing resin covers a surface of the top surface portion on a side farther from the first surface.

15. The module according to claim 4, wherein
the first sealing resin covers a surface of the top surface portion on a side farther from the first surface.

16. The module according to claim 2, wherein
when viewed in a direction perpendicular to the first surface, the first sealing resin extends to an outer side of the shield member, and
the module comprises an outer shield film covering a side surface of the first sealing resin and covering an upper surface of the first sealing resin or an upper surface of the shield member.

17. The module according to claim 3, wherein
when viewed in a direction perpendicular to the first surface, the first sealing resin extends to an outer side of the shield member, and
the module comprises an outer shield film covering a side surface of the first sealing resin and covering an upper surface of the first sealing resin or an upper surface of the shield member.

18. The module according to claim 4, wherein
when viewed in a direction perpendicular to the first surface, the first sealing resin extends to an outer side of the shield member, and
the module comprises an outer shield film covering a side surface of the first sealing resin and covering an upper surface of the first sealing resin or an upper surface of the shield member.

19. The module according to claim 5, wherein
when viewed in a direction perpendicular to the first surface, the first sealing resin extends to an outer side of the shield member, and
the module comprises an outer shield film covering a side surface of the first sealing resin and covering an upper surface of the first sealing resin or an upper surface of the shield member.

20. The module according to claim 6, wherein
when viewed in a direction perpendicular to the first surface, the first sealing resin extends to an outer side of the shield member, and
the module comprises an outer shield film covering a side surface of the first sealing resin and covering an upper surface of the first sealing resin or an upper surface of the shield member.
